(19) United States
(12) Patent Application Publication
(10) Pub. No.: US 2007/0210817 A1
(43) Pub. Date: Sep. 13, 2007

(54) Partitioned multi-die wafer-sort probe card and methods of using same

(75) Inventors: Bassam Dabit, Ramleh (IL); Doron Suchi, Jerusalem (IL); Igal Gurvits, Qiryat-Gal (IL); Eli Koreh, Ashdod (IL)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 11/521,912

(22) Filed: Sep. 15, 2006

Related U.S. Application Data
(63) Continuation of application No. 11/323,240, filed on Dec. 30, 2005.

(51) Int. Cl. G01R 31/02

(52) U.S. Cl. 324/758

(57) ABSTRACT

A partitioned multi-die wafer-sort probe card includes an arcuate unit pattern. The arcuate unit pattern is repeated, either in complete or truncated form across the footprint of the multi-die wafer-sort probe card. Wafer testing is carried out by first testing at a first touchdown (TD), stepping the multi-die wafer-sort probe card footprint at least one die-site dimension, and second testing at a second TD.

This application is a continuation of U.S. patent application Ser. No. 11/323,240, filed on Dec. 30, 2005, which is incorporated herein by reference.

### TECHNICAL FIELD

Embodiments relate generally to probe cards for testing integrated circuits on a wafer.

### TECHNICAL BACKGROUND

In the manufacture of semiconductor devices, it is advisable that such devices be tested at the wafer level to evaluate their functionality. The process in which die in a wafer are tested is commonly referred to as “wafer sort.” Testing and determining design flaws at the die level offers several advantages. First, it allows designers to evaluate the functionality of new devices during development. Increasing packaging costs also make wafer sorting a viable cost saver, in that reliability of each die on a wafer may be tested before incurring the higher costs of packaging. Measuring reliability also allows the performance of the production process to be evaluated and production consistency rated, such as for example by “bin switching” whereby the performance of a wafer is downgraded because that wafer's performance did not meet the expected criteria.

The process of die-test and wafer sort can be carried out with a wafer probe card. Die test is time consuming and costly and throughput is a significant factor in producing what is referred to as “known good die” for further processing such as packaging the known good die.

FIG. 7 is top plan 700 of footprints on a wafer that are produced by a conventional multi-die wafer-sort probe card. A wafer 1 is illustrated, pre-dicing, as an array of finished semiconductive devices that are arrayed within the circumference of the wafer 1. The wafer 1 is disposed upon a wafer-sort chuck 2. The footprint 3 of a wafer probe card is delineated by an X-dimension 4 and a Y-dimension 5. FIG. 7 illustrates that during die-test and wafer-sort, the footprint 3 of the wafer probe card must be stepped five times after the first touching down on the wafer 1. Accordingly, a total of six touchdowns is required.

### BRIEF DESCRIPTION OF THE DRAWINGS

In order to depict the manner in which the embodiments are obtained, a more particular description of embodiments briefly described above will be rendered by reference to exemplary embodiments that are illustrated in the appended drawings. These drawings depict typical embodiments that are not necessarily drawn to scale and are not therefore to be considered to be limiting of its scope. The embodiments will be described and explained with additional specificity and detail through the use of the accompanying drawings in which:

FIG. 1 is a top plan of a footprint produced by a multi-die wafer-sort probe card according to an embodiment;

FIG. 2 is a top plan of a footprint path produced by a multi-die wafer-sort probe card upon a wafer during wafer-sort testing according to an embodiment;

FIG. 3 is a top plan of a footprint path produced by a multi-die wafer-sort probe card upon a wafer during wafer-sort testing according to an embodiment;

FIG. 4 is a top plan of a footprint path produced by a multi-die wafer-sort probe card upon a wafer during wafer-sort testing according to an embodiment;

FIG. 5 is a top plan of a footprint path produced by a multi-die wafer-sort probe card upon a wafer during wafer-sort testing according to an embodiment;

FIG. 6 is a flow chart that describes process and method flow embodiments;

FIG. 7 is top plan of footprints produced by a conventional multi-die wafer-sort probe card.

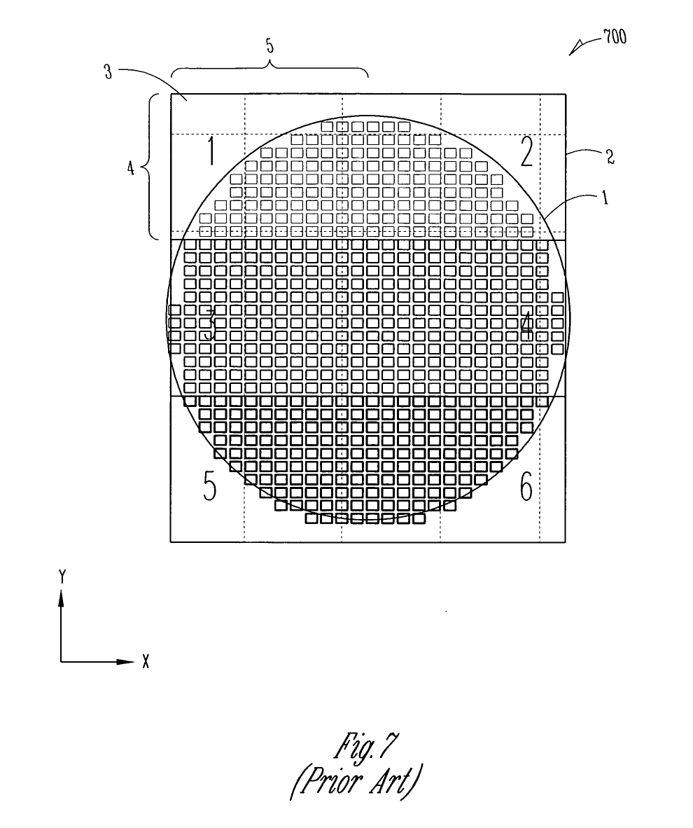

### DETAILED DESCRIPTION

Embodiments in this disclosure relate multi-die wafer-sort probe cards.

The following description includes terms, such as upper, lower, first, second, etc. that are used for descriptive purposes only and are not to be construed as limiting. The embodiments of an apparatus or article described herein can be manufactured, used, or shipped in a number of positions and orientations. The terms “die” and “chip” generally refer to the physical object that is the basic workpiece that is transformed by various process operations into the desired integrated circuit device. A die is usually singulated from a wafer, and wafers may be made of semiconducting, non-semiconducting, or combinations of semiconducting and non-semiconducting materials.

Reference will now be made to the drawings wherein like structures may be provided with like suffix reference designations. In order to show the structures of various embodiments most clearly, the drawings included herein are diagrammatic representations of integrated circuit structures. Thus, the actual appearance of the fabricated structures, for example in a photomicrograph, may appear different while still incorporating the essential structures of the illustrated embodiments. Moreover, the drawings show the structures necessary to understand the illustrated embodiments. Additional structures known in the art have not been included to maintain the clarity of the drawings.

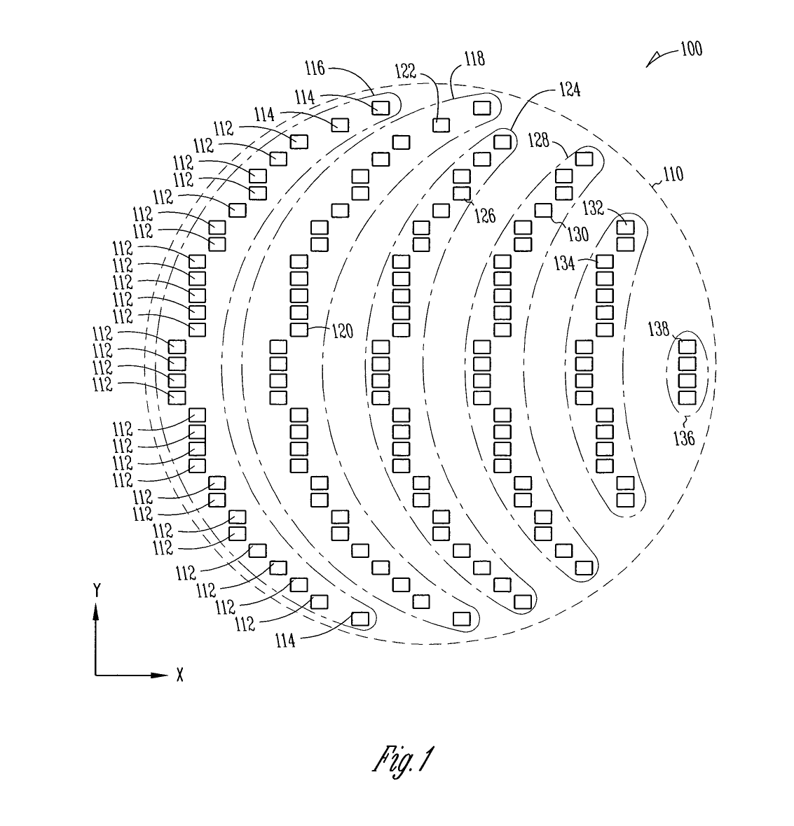

FIG. 1 is a top plan 100 of a detailed footprint 110 produced by a multi-die wafer-sort probe card according to an embodiment. The probe card footprint 110 is depicted only schematically and with a circumference in a dashed line with respect to the detailed footprint 110. A plurality of die-test sites is depicted, several of which are delineated with the reference numerals 112 and 114.

In an embodiment, a plurality of die-test sites 112 and 114 exhibits an overall curvilinear shape. In an embodiment, the overall curvilinear shape is a crescent shape. The overall curvilinear shape is encompassed in an envelope 116 drawn by the applicants for illustrative purposes. Accordingly, the envelope 116 encompasses discrete die-test sites 112 and 114.

In an embodiment, the envelope 116 encompasses a unit pattern of die-test sites 112 and 114. The unit pattern in this embodiment includes a first group of serially contiguous die-test sites 112 and a second group of isolated die-test sites 114. By “serially contiguous” it is meant that a single die-test site is immediately next to only one other die-test site on the probe card footprint, when viewing the group in a linear series. By “isolated” it is meant that a single die-test site in not immediately next to any other die-test site on the probe card footprint. In FIG. 1, the first group of serially contiguous die-test sites 112 is larger than the second group of isolated die-test sites 114.

FIG. 1 also depicts a second unit pattern within an envelope 118 drawn by the applicants for illustrative purposes. The second unit pattern within the envelope 118 is identical to the first unit pattern within the envelope 116. Accordingly, the unit pattern in this embodiment includes a first group of serially contiguous die-test sites 120, one of which is indicated, and a second group of isolated die-test sites 122, also one of which is indicated.

FIG. 1 also depicts a third pattern within an envelope 124 drawn by the applicants for illustrative purposes. The third pattern is a truncated portion of the unit pattern that is within the envelopes 116 or 118. Also within the envelope is a section of a unit pattern that is identical to the first unit pattern within the envelope 116. Accordingly, the unit pattern in this embodiment includes a first group of serially contiguous die-test sites 126, one of which is indicated.

FIG. 1 also depicts a fourth pattern within an envelope 128 drawn by the applicants for illustrative purposes. The fourth pattern is a truncated portion of the unit pattern that is within the envelopes 116 or 118. Similarly, the fourth pattern is a further truncated portion of the third pattern. Accordingly, the truncated unit pattern in this embodiment includes a first group of serially contiguous die-test sites 130, one of which is indicated.

FIG. 1 also depicts a fifth pattern within an envelope 132 drawn by the applicants for illustrative purposes. The fifth pattern is a truncated portion of the unit pattern that is within the envelopes 116 or 118. Similarly, the fifth pattern is a further truncated portion of the third pattern. And also similarly, the fifth pattern is a further truncated portion of the fourth pattern. Accordingly, the truncated unit pattern in this embodiment includes a first group of serially contiguous die-test sites 134, one of which is indicated.

FIG. 1 also depicts a sixth pattern within an envelope 136 drawn by the applicants for illustrative purposes. The sixth pattern is a truncated portion of the unit pattern that is within the envelopes 116 or 118. Similarly, the sixth pattern is a further truncated portion of the third pattern. Also similarly, the sixth pattern is a further truncated portion of the fourth pattern. And also similarly, the sixth pattern is a further truncated portion of the fifth pattern. Accordingly, the truncated unit pattern in this embodiment includes a first group of serially contiguous die-test sites 138, one of which is indicated.

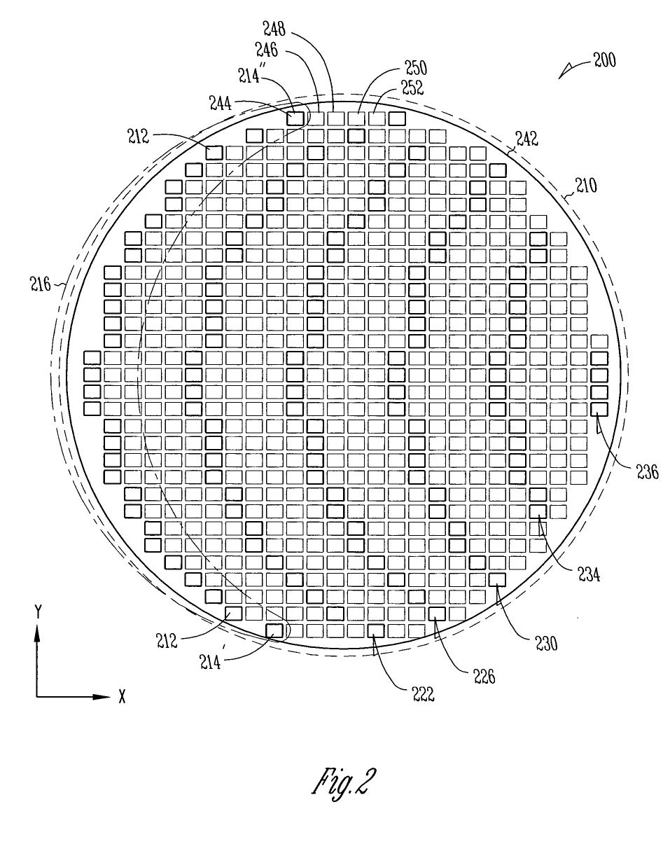

FIG. 2 is a top plan 200 of a detailed footprint path produced by a multi-die wafer-sort probe card footprint 210 upon a wafer during wafer-sort testing according to an embodiment. The probe card footprint 210, depicted in a dashed circle, is superimposed over a wafer 240. A unit pattern of die-test sits is depicted with an overall curvilinear shape is encompassed in an envelope 216 drawn by the applicants for illustrative purposes. Accordingly, the envelope 216 encompasses discrete die-test sites 212 and 214 that make up the unit pattern. The unit pattern can be described as beginning at die-test site 214′ at the bottom of the figure, and proceeding clockwise along the edge of the multi-die wafer-sort probe card footprint 210, ending at the die-test site 214″.

A second unit pattern is seen beginning at a die-test site 222. A truncated unit pattern is seen beginning at die-test site 226. The truncated unit pattern beginning a die-test site 226 is also a continuous, albeit a truncated unit pattern of serially contiguous die-test sites. Another truncated unit pattern is seen beginning at die-test site 230. The truncated unit pattern beginning a die-test site 230 is also a continuous, albeit a truncated unit pattern of serially contiguous die-test sites. Yet another truncated unit pattern is seen beginning at die-test site 234. The truncated unit pattern beginning a die-test site 234 is also a continuous, albeit a truncated unit pattern of serially contiguous die-test sites. And subsequently, another truncated unit pattern is seen beginning at die-test site 236, which includes four die-test sites in a single row. The truncated unit pattern beginning a die-test site 236 is also a continuous, albeit a truncated unit pattern of serially contiguous die-test sites.

In a first process embodiment, the unit pattern within the envelope 216 is moved by stepping the multi-die wafer-sort probe card a discrete distance that is equivalent to a factor of a single die-site dimension. In FIG. 2, the stepping moves the die-test site 214″ from the die site 244 (hidden below the die-test site 214′) to the subsequent die-site 246. Accordingly, each die-test site represented by the 10 multi-die wafer-sort probe card footprint 210 moves equally by a single die-site dimension in the positive-X direction.

In subsequent process embodiments, the unit pattern within the envelope 216 of the multi-die wafer-sort probe card footprint 210 is again stepped one die site such that the die-test site 214″ moves further from the die site 246 to the die site 248, to the die site 250, and ultimately to the die site 252. By this illustrative embodiment, it becomes clear that no die to test in the first plurality tested die sites is included in the subsequent plurality of die sites to test. And where testing each die at each die site is carried out, the multi-die wafer-sort probe card in this embodiment has tested all die sites in five touchdowns (TDs) by the serial 20 movement of the probe card footprint 210. Although die-test sites that are at the edge of the wafer 242, are moved off from the wafer during die-test, a significant number of die-test sites are employed compared to conventional use of a probe card.

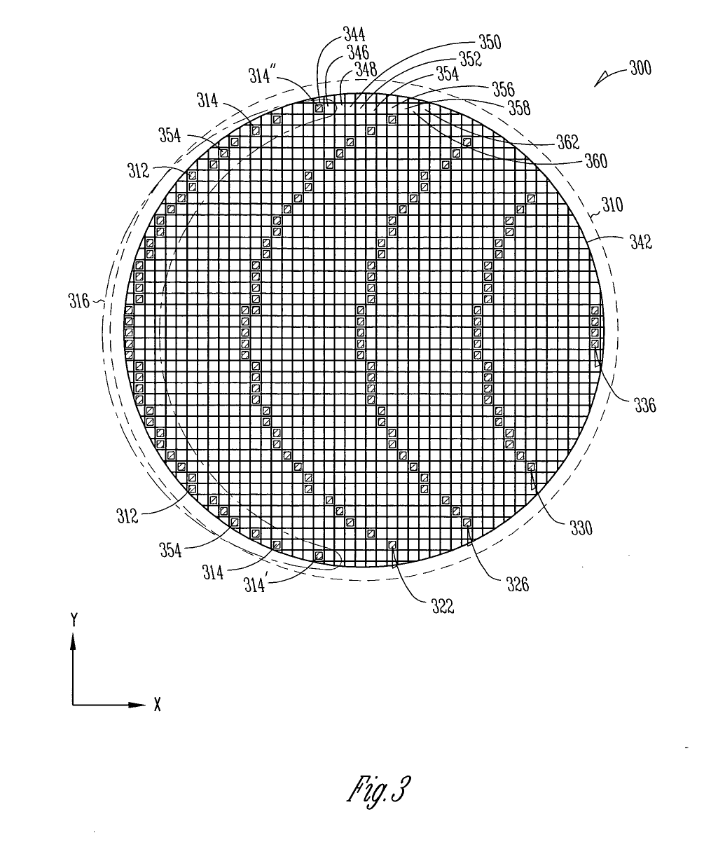

FIG. 3 is a top plan 300 of a detailed footprint path produced by a multi-die wafer-sort probe card footprint 310 upon a wafer 342 during wafer-sort testing according to an embodiment. The probe card footprint 310, depicted in a dashed circle, is superimposed over the wafer 342. A unit pattern of die-test sites is depicted with an overall curvilinear shape is encompassed in an envelope 316 drawn by the applicants for illustrative purposes. Accordingly, the envelope 316 encompasses discrete die-test sites 312, which are serially contiguous in a first 30 group, discrete die-test sites 314, which are isolated die-test sites in a second group, and discrete die-test sites 354, which are serially contiguous in a third group and in a fourth group. The third group and the fourth group in this embodiment have equal numbers of die-test sites. In any event, the first group, second group, third group, and fourth group make up the unit pattern in FIG. 3. The unit pattern can be described as beginning at die-test site 314′ at the bottom of the figure, and proceeding clockwise along the edge of the footprint 310, ending at the die-test site 314″.

A truncated unit pattern is seen beginning at a die-test site 322. The truncated unit pattern beginning a die-test site 322 includes both serially contiguous and isolated die-test sites. A truncated unit pattern is seen beginning at die-test site 326. The truncated unit pattern beginning a die-test site 326 includes three separate groups of serially contiguous die-test sites. Another truncated unit pattern is seen beginning at die-test site 330. The truncated unit pattern beginning at die-test site 330 is also a continuous, albeit a truncated unit pattern of serially contiguous die-test sites. Yet another truncated unit pattern is seen beginning at die-test site 336.

The truncated unit pattern beginning a die-test site 336 is also a continuous, albeit a truncated unit pattern of serially die-test sites equaling four in number.

In a first process embodiment, the unit pattern within the envelope 316 is moved by stepping the multi-die wafer-sort probe card a discrete distance that is equivalent to a factor of a single die-site dimension. In FIG. 3, the stepping process moves a die-test site 314″ from the die site 344 (hidden below the die-test site 314″) to the subsequent die-site 346. Accordingly, each die-test site represented by the multi-die wafer-sort probe card footprint 310 moves equally by a single die-site dimension in the positive-X direction.

In subsequent process embodiments, the unit pattern within the envelope 316 is again stepped one die site on the wafer 342 such that the die-test site 314″ moves further from the die site 346 to the die site 348, to the die site 350, to the die site 352, to the die site 354, to the die site 354, to the die site 356, to the die site 358, to the die site 360, and ultimately to die site 362. Accordingly where testing each die at each die site is carried out, the multi-die wafer-sort probe card in this embodiment has tested all die sites in eleven TDs. Although die-test sites that are at the edge of the wafer 342, are moved off the wafer during die-test, a significant number of die-test sites are employed compared to conventional use of a probe card.

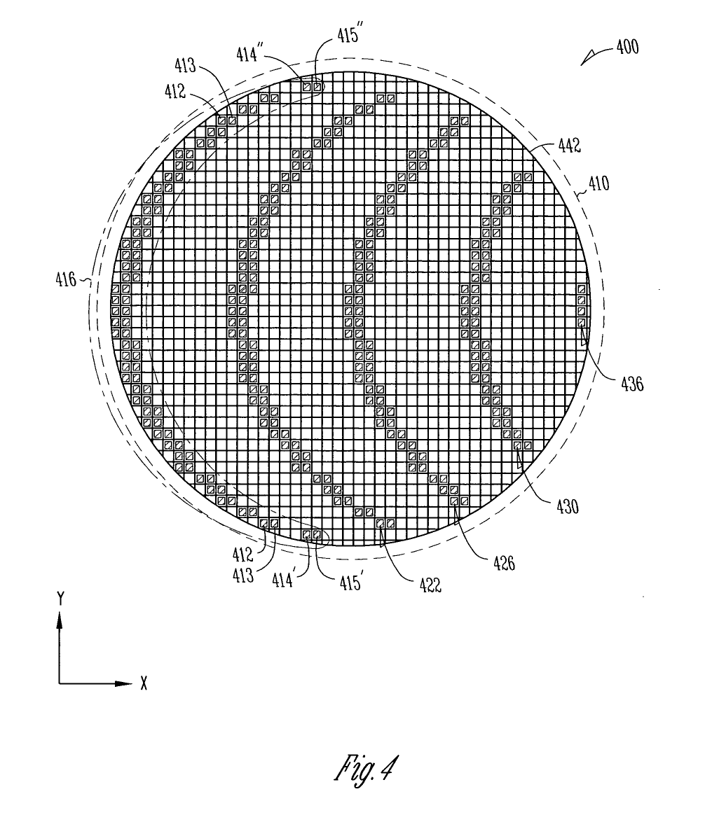

FIG. 4 is a top plan 400 of a detailed footprint path produced by a multi-die wafer-sort probe card footprint 410 upon a wafer 442 during wafer-sort testing according to an embodiment. The multi-die wafer-sort probe card footprint 410, depicted in a dashed circle, is superimposed over the wafer 442. A unit pattern of die-test sites is depicted with an overall curvilinear shape is encompassed in an envelope 416 drawn by the applicants for illustrative purposes. Accordingly, the envelope 416 encompasses discrete die-test sites 412 and 413, which are serially contiguous in a first group, and discrete die-test sites 414 and 415, which are serially contiguous in a second group and in a third group. The second group and the third group in this embodiment have equal numbers of die-test sites. In any event, the first group, second group and third group make up the unit pattern within the envelope 416 in FIG. 4. The unit pattern can be described as beginning at the die-test sites 414′ and 415′ at the bottom of the figure, and proceeding clockwise along the edge of the footprint 410, ending at the die-test site 414″ 415″. The die-test sites are doubled laterally, such that during test, the footprint 410 of the probe card must touch down only six times instead of eleven as illustrated in FIG. 3.

A truncated unit pattern is seen beginning at a die-test site 422. The truncated unit pattern beginning a die-test site 422 includes all serially contiguous die-test sites. A truncated unit pattern is seen beginning at die-test site 426. The truncated unit pattern beginning a die-test site 426 includes serially contiguous die-test sites. Another truncated unit pattern is seen beginning at die-test site 430. The truncated unit pattern beginning at die-test site 430 is also a continuous, albeit a truncated unit pattern of serially contiguous die-test sites. Yet another truncated unit pattern is seen beginning at die-test site 436. The truncated unit pattern beginning a die-test site 436 is also a continuous, albeit a truncated unit pattern of serially die-test sites equaling four in number.

In a first process embodiment, the unit pattern within the envelope 416 is moved by stepping the multi-die wafer-sort probe card footprint 410 a discrete distance that is equivalent to a factor of twice a single die-site dimension. The process embodiment is otherwise similar to the process embodiments illustrated in FIG. 3. Accordingly, each die-test site represented by the multi-die wafer-sort probe card footprint 410 moves equally by a double die-site dimension in the positive-X direction. Accordingly where testing each die at each die site is carried out, the multi-die wafer-sort probe card in this embodiment has tested all die sites in six TDs. Although die-test sites that are at the edge of the wafer 442, are moved off the wafer during die-test, a significant number of die-test sites are employed compared to conventional use of a probe card.

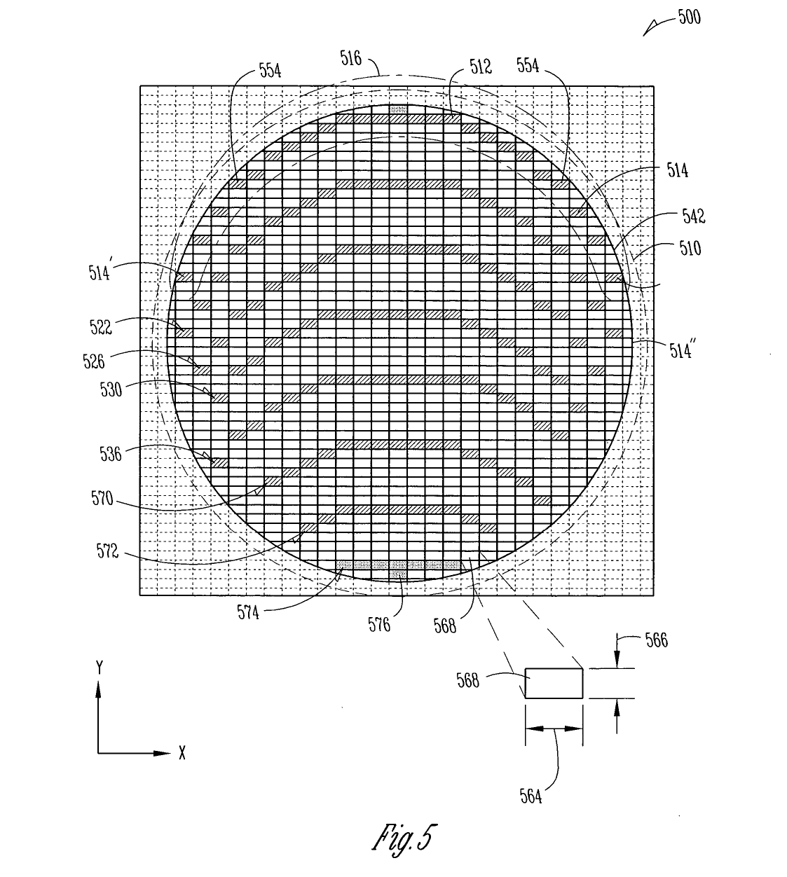

FIG. 5 is a top plan 500 of a detailed footprint path produced by a multi-die wafer-sort probe card footprint 510 upon a wafer 542 during wafer-sort testing according to an embodiment. The multi-die wafer-sort probe card footprint 510, depicted in a dashed circle, is superimposed over the wafer 542. In an embodiment, each die site on the wafer 542 has an aspect ratio, the X-dimension 564 divided by the Y-dimension 566, of greater than one. In an embodiment, each die site on the wafer 542 has an aspect ratio, the X-dimension 564 divided by the Y-dimension 566, of equal to one. In an embodiment, each die site on the wafer 542 has an aspect ratio, the X-dimension 564 divided by the Y-dimension 566, of less than one.

A detail 568 of one die site is extracted to illustrate the aspect ratio of the X-dimension 564 divided by the Y-dimension 566 being greater than one. During the process of die-test in the embodiment where the aspect ratio of the X-dimension divided by the Y-dimension is greater than one, stepping occurs in the negative-Y direction according to an embodiment. During the process of die-test in the embodiment where the aspect ratio of the X-dimension divided by the Y-dimension is greater than one, stepping occurs in the positive-Y direction according to an embodiment. During the process of die-test in the embodiment where the aspect ratio of the X-dimension divided by the Y-dimension is greater than one, stepping occurs in the positive-X direction, similar to what is illustrated in FIG. 3, according to an embodiment. During the process of die-test in the embodiment where the aspect ratio of the X-dimension divided by the Y-dimension is greater than one, stepping occurs in the negative-X direction, similar to a mirror-image of what is illustrated in FIG. 3, according to an embodiment. The Table illustrates several embodiments for X:Y aspect ratios and stepping direction embodiments in combination. The first four examples, 1, 2, 3, and 4 are set forth in this paragraph.

TABLE
X:Y Ratios and Stepping Directions

| | Die-Site | | | | |
|---|---|---|---|---|---|
| Examples | Ratio, | Stepping | Stepping | Stepping | Stepping |
| No. | X:Y | direction | direction | direction | direction |
| 1, 2, 3, 4 | >1 | Negative-Y | Positive-Y | Positive-X | Negative-X |
| 5, 6, 7, 8 | =1 | Negative-Y | Positive-Y | Positive-X | Negative-X |
| 9, 10, | <1 | Negative-Y | Positive-Y | Positive-X | Negative-X |
| 11, 12 | | | | | |

In an embodiment, the die sites on the wafer 542 each have a rectangular aspect ratio of about 1:1. In an embodiment, the die sites on the wafer 542 each have a rectangular aspect ratio of, about 1:1.025. In an embodiment, the die sites on the wafer 542 each have a rectangular aspect ratio of about 1:1.05. In an embodiment, the die sites on the wafer 542 each have a rectangular aspect ratio of about 1:1.075. In an embodiment, the die sites on the wafer 542 each have a rectangular aspect ratio of about 1:1.1. In an embodiment, the die sites on the wafer 542 each have a rectangular aspect ratio of about 1:1.125. In an embodiment, the die sites on the wafer 542 each have a rectangular aspect ratio of about 1:1.15. In an embodiment, the die sites on the wafer 542 each have a rectangular aspect ratio of about 1:1.175. In an embodiment, the die sites on the wafer 542 each have a rectangular aspect ratio of about 1:1.2. In an embodiment, the die sites on the wafer 542 each have a rectangular aspect ratio of about 1:1.225. In an embodiment, the die sites on the wafer 542 each have a rectangular aspect ratio of about 1:1.25. In an embodiment, the die sites on the wafer 542 each have a rectangular aspect ratio of about 1:1.275. In an embodiment, the die sites on the wafer 542 each have a rectangular aspect ratio of about 1:1.3. In an embodiment, the die sites on the wafer 542 each have a rectangular aspect ratio of about 1:1.325. In an embodiment, the die sites on the wafer 542 each have a rectangular aspect ratio of about 1:1.35. In an embodiment, the die sites on the wafer 542 each have a rectangular aspect ratio of about 1:1.375. In an embodiment, the die sites on the wafer 542 each have a rectangular aspect ratio of about 1:1.4. In an embodiment, the die sites on the wafer 542 each have a rectangular aspect ratio of about 1:1.425. In an embodiment, the die sites on the wafer 542 each have a rectangular aspect ratio of about 1:1.45. In an embodiment, the die sites on the wafer 542 each have a rectangular aspect ratio of about 1:1.475. In an embodiment, the die sites on the wafer 542 each have a rectangular aspect ratio of about 1:1.5. In an embodiment, the die sites on the wafer 542 each have a rectangular aspect ratio of about 1:1.525. In an embodiment, the die sites on the wafer 542 each have a rectangular aspect ratio of about 1:1.55. In an embodiment, the die sites on the wafer 542 each have a rectangular aspect ratio of about 1:1.575. In an embodiment, the die sites on the wafer 542 each have a rectangular aspect ratio of about 1:1.6. In an embodiment, the die sites on the wafer 542 each have a rectangular aspect ratio of about 1:1.625. In an embodiment, the die sites on the wafer 542 each have a rectangular aspect ratio of about 1:1.65. In an embodiment, the die sites on the wafer 542 each have a rectangular aspect ratio of about 1:1.675. In an embodiment, the die sites on the wafer 542 each have a rectangular aspect ratio of about 1:1.7. In an embodiment, the die sites on the wafer 542 each have a rectangular aspect ratio of about 1:1.725. In an embodiment, the die sites on the wafer 542 each have a rectangular aspect ratio of about 1:1.75. In an embodiment, the die sites on the wafer 542 each have a rectangular aspect ratio of about 1:1.775. In an embodiment, the die sites on the wafer 542 each have a rectangular aspect ratio of about 1:1.8. In an embodiment, the die sites on the wafer 542 each have a rectangular aspect ratio of about 1:1.825. In an embodiment, the die sites on the wafer 542 each have a rectangular aspect ratio of about 1:1.85. In an embodiment, the die sites on the wafer 542 each have a rectangular aspect ratio of about 1:1.875. In an embodiment, the die sites on the wafer 542 each have a rectangular aspect ratio of about 1:1.9. In an embodiment, the die sites on the wafer 542 each have a rectangular aspect ratio of about 1:1.925. In an embodiment, the die sites on the wafer 542 each have a rectangular aspect ratio of about 1:1.95. In an embodiment, the die sites on the wafer 542 each have a rectangular aspect ratio of about 1:1.975. In an embodiment, the die sites on the wafer 542 each have a rectangular aspect ratio of and about 1:2. In an embodiment, the die sites on the wafer 542 each have a rectangular aspect ratio of greater than 1:2.

In complementary individual embodiments, for each X:Y ratio embodiment set forth above, the X:Y ratio is reversed, such that each given numerical ratio embodiment is a Y:X ratio embodiment.

A unit pattern of die-test sites of the multi-die wafer-sort probe card footprint 510 is depicted with an overall curvilinear shape is encompassed in an envelope 516 drawn by the applicants for illustrative purposes. Accordingly, the envelope 516 encompasses discrete die-test sites 512, which are serially contiguous in a first group, discrete die-test sites 514, which are isolated in a second group, and discrete die-test sites 554, which are serially contiguous in a third and a fourth group. The third group and the fourth group in this embodiment have equal numbers of die-test sites. In any event, the first group, second group, third group, and fourth group make up the unit pattern within the envelope 516 in FIG. 5. The unit pattern can be described as beginning at the die-test site 514′ at the left edge of the figure, and proceeding clockwise along the edge of the footprint 510, ending at the die-test sites 514″.

A second unit pattern is seen beginning at a die-test site 522. The second unit pattern beginning a die-test site 522 includes both serially contiguous and isolated die-test sites identically to the first unit pattern that is shown within the envelope 516 in this embodiment. A truncated unit pattern is seen beginning at die-test site 526. The truncated unit pattern beginning a die-test site 526 includes both serially contiguous and isolated die-test sites. Another truncated unit pattern is seen beginning at die-test site 530. The truncated unit pattern beginning at die-test site 530 is also a continuous, albeit a truncated unit pattern of serially contiguous and isolated die-test sites. Yet another truncated unit pattern is seen beginning at die-test site 536. The truncated unit pattern beginning a die-test site 536 is also a continuous, albeit a truncated unit pattern of serially contiguous and isolated die-test sites. Yet another truncated unit pattern is seen beginning at die-test site 570. The truncated unit pattern beginning a die-test site 570 is also a continuous, albeit a truncated unit pattern of serially contiguous die-test sites. Yet another truncated unit pattern is seen beginning at die-test site 572. The truncated unit pattern beginning a die-test site 572 is also a continuous, albeit a truncated unit pattern of serially contiguous die-test sites. And finally in FIG. 5, another truncated unit pattern is seen beginning at die-test site 574. The truncated unit pattern beginning a die-test site 574 is also a truncated unit pattern of serially contiguous die-test sites equaling seven in number, with a single die-test site 576 added to cover a single die-site at the edge of the wafer 542.

In a first process embodiment, the unit pattern within the envelope 516 is moved by stepping the multi-die wafer-sort probe card footprint 510 a discrete distance along the Y-axis that is equivalent to a factor of a single die-site dimension. Accordingly, where testing each die at each die site is carried out, the multi-die wafer-sort probe card in this embodiment has tested all die sites in seven TDs. Although die-test sites that are at the edge of the wafer 542, are moved off the wafer during die-test, a significant number of die-test sites are employed compared to conventional use of a probe card.

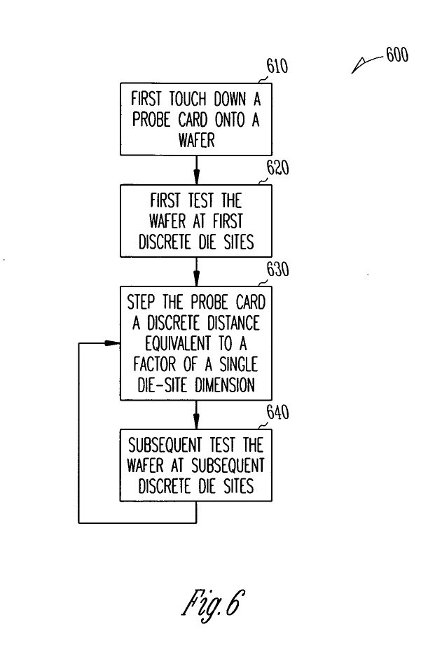

FIG. 6 is a flow chart that describes process and method flow embodiments. At 610, the process includes first touching down a multi-die wafer-sort probe card embodiment disclosed herein onto a wafer at a first location.

At 620, the process includes first testing first discrete die sites that are contacted by die-test sites on the probe card.

At 630, the process includes stepping the multi-die wafer-sort probe card a discrete distance that is equivalent to a factor of a single die-site dimension. In an embodiment, the factor is one. In an embodiment, the factor is two. In an embodiment, the factor is greater than two and less than eleven.

At 640, the process includes subsequent testing the wafer at subsequent die-test sites. In an embodiment, the process flows back to 630 to step the multi-die wafer-sort probe card to yet another subsequent die-test site. As illustrated in non-limiting embodiments, this action can be repeated eleven times or more depending upon the design of the multi-die wafer-sort probe card with respect to the wafer that is being tested.

Several types of wafers are testable according to the various embodiments and their equivalents, now that this disclosure is provided. In an embodiment, a wafer is tested that contains an array of microelectronic devices that to be singulated as flash memory dice. In an embodiment, a wafer is tested that contains an array of microelectronic devices that to be singulated as dynamic random access memory (DRAM) dice. In an embodiment, a wafer is tested that contains an array of microelectronic devices that to be singulated as polymer memory dice. In an embodiment, a wafer is tested that contains an array of microelectronic devices that to be singulated as phase-change memory dice. In an embodiment, a wafer is tested that contains an array of microelectronic devices that to be singulated as processor dice. In an embodiment, a wafer is tested that contains an array of microelectronic devices that to be singulated as digital signal processor (DSP) dice. In an embodiment, a wafer is tested that contains an array of microelectronic devices that to be singulated as micro controller dice. In an embodiment, a wafer is tested that contains an array of microelectronic devices that to be singulated as application specific integrated circuit (ASIC) dice. In an embodiment, a wafer is tested that contains an array of microelectronic devices that to be singulated as microprocessor dice.

It can now be appreciated that article and process embodiments set forth in this disclosure can be applied to test various devices.

The Abstract is provided to comply with 37 C.F.R. § 1.72(b) requiring an abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

What is claimed is:

1. An article comprising:
a multi-die wafer-sort including a plurality of die-test sites arranged in a series of unit patterns, wherein a unit pattern exhibits an overall curvilinear shape of discrete die-test sites.

2. The article of claim 1, wherein the overall curvilinear shape is a crescent shape of the discrete die-test sites.

3. The article of claim 1, wherein within a first unit pattern, the discrete die-test sites are arranged in a first group of serially contiguous die-test sites and in a second group of isolated die-tests sites, and wherein the first group is larger than the second group.

4. The article of claim 1, wherein within a first unit pattern, the discrete die-test sites are arranged in a first group of serially contiguous die-test sites, in a second group of isolated die-tests sites, and in a third group of serially contiguous die-test sites, and wherein the first group is larger than the third group.

5. The article of claim 1, wherein within a first unit pattern, the discrete die-test sites are arranged in a first group of serially contiguous die-test sites, in a second group of isolated die-tests sites, in a third group of serially contiguous die-test sites, in a fourth group of serially contiguous die-test sites, wherein the first group is larger than the third group, wherein the first group is larger than the fourth group, and wherein the third group of die-test sites equals the fourth group of die-test sites.

6. The article of claim 1, wherein the series of unit patterns includes at least one complete unit pattern, and at least one truncated unit pattern.

7. The article of claim 1, wherein the series of unit patterns includes at least one complete unit pattern, and at least one truncated unit pattern.

8. The article of claim 1, wherein the series of unit patterns includes at least one complete unit pattern, and at least one truncated unit pattern, and wherein the at least one truncated unit pattern exhibits only serially contiguous die-test sites.

9. The article of claim 1, wherein the series of unit patterns includes at least one complete unit pattern, and at least one truncated unit pattern, and wherein the at least one truncated unit pattern exhibits both serially contiguous die-test sites and isolated die-tests sites.

10. The article of claim 1, wherein the die-test sites have a rectangular aspect ratio selected from about 1:1, about 1:1.025, about 1:1.05, about 1:1.075, about 1:1.1, about 1:1.125, about 1:1.15, about 1:1.175, about 1:1.2, about 1:1.225, about 1:1.25, about 1:1.275, about 1:1.3, about 1:1.325, about 1:1.35, about 1:1.375, about 1:1.4, about 1:1.425, about 1:1.45, about 1:1.475, about 1:1.5, about 1:1.525, about 1:1.55, about 1:1.575, about 1:1.6, about 1:1.625, about 1:1.65, about 1:1.675, about 1:1.7, about 1:1.725, about 1:1.75, about 1:1.775, about 1:1.8, about 1:1.825, about 1:1.85, about 1:1.875, about 1:1.9, about 1:1.925, about 1:1.95, about 1:1.975, about 1:2, and greater than about 1:2.

11. An article comprising:
a multi-die wafer-sort including a plurality of die-test sites arranged in a series of unit patterns, wherein a unit pattern exhibits an overall crescent shape of discrete die-test sites, wherein within the unit pattern, the discrete die-test sites are arranged in a first group of serially contiguous die-test sites and in a second group of isolated die-tests sites, and wherein the first group is larger than the second group.

12. The article of claim 11, wherein within the unit pattern, the discrete die-test sites are arranged in a first group of serially contiguous die-test sites, in a second group of isolated die-tests sites, and in a third group of serially contiguous die-test sites, and wherein the first group is larger than the third group.

13. The article of claim 11, wherein the series of unit patterns includes at least one complete unit pattern, and at least one truncated unit pattern.

14. The article of claim 11, wherein the series of unit patterns includes at least one complete unit pattern, and at least one truncated unit pattern.

15. The article of claim 1, wherein the series of unit patterns includes at least one complete unit pattern, and at least one truncated unit pattern, and wherein the at least one truncated unit pattern exhibits only serially contiguous die-test sites.

16. A method comprising:
first touching down a multi-die wafer-sort probe card onto a wafer, the probe card including a plurality of die-test sites arranged in a series of unit patterns, wherein a first unit pattern exhibits an overall curvilinear shape of discrete die-test sites;
testing the wafer at the discrete test sites;
stepping the multi-die wafer-sort probe card a discrete distance equivalent to a factor of a single die-site dimension; and
subsequent touching down the multi-die wafer-sort probe card onto the wafer.

17. The method of claim 16, wherein first touching down the multi-die wafer-sort probe card onto the wafer the achieves test contact with a first plurality of die sites to test, and wherein subsequent touching down achieves test contact with a subsequent plurality of die sites to test, and wherein no die site to test in the first plurality is included in the subsequent plurality of die sites to test.

18. The method of claim 16, wherein the wafer includes a plurality of die sites to test, wherein each die site in the plurality of die sites to test has an X-Y aspect ratio, and wherein when X is greater than Y, then the stepping the probe card of a discrete distance equivalent to a factor of a single die-site dimension, is carried out, selected from the positive-Y direction, the negative-Y direction, the positive-X direction, and the negative-X direction.

19. The method of claim 16, wherein the wafer includes a plurality of die sites to test, wherein each die site in the plurality of die sites to test has an X-Y aspect ratio, and wherein when X is equal to Y, then the stepping the probe card of a discrete distance equivalent to a factor of a single die-site dimension, is carried out, selected from the positive-Y direction, the negative-Y direction, the positive-X direction, and the negative-X direction.

20. The method of claim 16, wherein the wafer includes a plurality of die sites to test, wherein each die site in the plurality of die sites to test has an X-Y aspect ratio, and wherein when X is less than Y, then the stepping the probe card of a discrete distance equivalent to a factor of a single die-site dimension, is carried out, selected from the positive-Y direction, the negative-Y direction, the positive-X direction, and the negative-X direction.

21. The method of claim 16, wherein touching down the multi-die wafer-sort probe card onto the wafer includes touching a wafer containing an array of flash-memory containing die sites.

22. The method of claim 16, wherein the wafer includes a wafer with a die-site array dimensioned 26-by-36 die sites, and wherein touching down to test all integrated-circuit completed is accomplished in five touchdowns.

23. The method of claim 16, wherein the wafer includes a wafer with a die-site array dimensioned 45-by-41 die sites, and wherein touching down to test all integrated-circuit completed die sites is accomplished in eleven touchdowns.

24. The method of claim 16, wherein the wafer includes a wafer with a die-site array dimensioned 25-by-51 die sites, and wherein touching down to test all integrated-circuit completed die sites, less one, is accomplished in seven touchdowns.

25. The method of claim 16, wherein the wafer includes a wafer with a die-site array dimensioned 22-by-33 die sites, and wherein touching down to test all integrated-circuit completed die sites, less one, is accomplished in seven touchdowns.

26. The method of claim 16, wherein the wafer includes a wafer the probe card onto the wafer includes touching a wafer containing an array of flash-memory containing die sites.
